(19) United States
(12) Patent Application Publication
(10) Pub. No.: US 2009/0321952 A1
(43) Pub. Date: Dec. 31, 2009

(54) WIRE ON WIRE STITCH BONDING IN A SEMICONDUCTOR DEVICE

(76) Inventors: XingZhi Liang, ShangHai (CN); HaiBo Fang, ShangHai (CN); Li Wang, ShangHai (CN)

Correspondence Address: VIERRA MAGEN/SANDISK CORPORATION, 575 MARKET STREET, SUITE 2500, SAN FRANCISCO, CA, 94105, US

(21) Appl. No.: 12/165,391

(22) Filed: Jun. 30, 2008

(30) Foreign Application Priority Data
Jun. 27, 2008 (CN) 200810127580.5

(51) Int. Cl. H01L 23/49

(52) U.S. Cl. 257/777; 257/E23.024

(57) ABSTRACT

A low profile semiconductor package is disclosed including at least first and second stacked semiconductor die mounted to a substrate. The first semiconductor die may be electrically coupled to the substrate with a plurality of stitches in a forward ball bonding process. The second semiconductor die may in turn be electrically coupled to the first semiconductor die using a second set of stitches bonded between the die bond pads of the first and second semiconductor die. The second set of stitches may each include a lead end having a stitch ball that is bonded to the bond pads of the second semiconductor die. The tail end of each stitch in the second set of stitches may be wedge bonded directly to lead end of a stitch in the first set of stitches.

### CROSS-REFERENCE TO RELATED APPLICATION

The following application is cross-referenced and incorporated by reference herein in its entirety:

U.S. patent application Ser. No. ______ [Attorney Docket No. SAND-01335US0], entitled “Method of Fabricating Wire On Wire Stitch Bonding In A Semiconductor Device,” by Liang, et al., filed on even date herewith.

### PRIORITY CLAIM

This application claims priority to Chinese Application No. ______ filed Jun. 27, 2008 entitled Wire on Wire Stitch Bonding In A Semiconductor Device, with application is incorporated herein in its entirety.

### BACKGROUND OF THE INVENTION

1. Field of the Invention

Embodiments of the present invention relate to a low profile semiconductor device and method of fabricating same.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated as system-in-a-package (SiP) or multichip modules (MCM), where a functional system is assembled into a single package. An edge view of a conventional semiconductor package 20 (without molding compound) is shown in prior art FIGS. 1 and 2. Typical packages include a plurality of semiconductor die 22, 24 mounted to a substrate 26. Although not shown in FIGS. 1 and 2, the semiconductor die are formed with die bond pads on an upper surface of the die. Substrate 26 may be formed of an electrically insulating core sandwiched between upper and lower conductive layers. The upper and/or lower conductive layers may be etched to form conductance patterns including electrical leads and contact pads. Bond wires, referred to herein as stitches, are bonded between the die bond pads of the semiconductor die 22, 24 and the contact pads of the substrate 26 to electrically couple the semiconductor die to the substrate. The electrical leads on the substrate in turn provide an electrical path between the die and a host device. Once electrical connections between the die and substrate are made, the assembly is then typically encased in a molding compound to provide a protective package.

It is known to layer semiconductor die on top of each other either with an offset (prior art FIG. 1) or in a stacked configuration (prior art FIG. 2). In the offset configuration of FIG. 1, the die are stacked with an offset so that the bond pads of the next lower die are left exposed. Such configurations are shown for example in U.S. Pat. No. 6,359,340 to Lin, et al., entitled, “Multichip Module Having A Stacked Chip Arrangement.” An offset configuration provides an advantage of convenient access of the bond pads on each of the semiconductor die. However, the offset requires a greater footprint on the substrate, where space is at a premium.

In the stacked configuration of FIG. 2, two or more semiconductor die are stacked directly on top of each other, thereby taking up less footprint on the substrate as compared to an offset configuration. However, in a stacked configuration, space must be provided between adjacent semiconductor die for the wire stitches 30. In addition to the height of the stitches 30 themselves, additional space must be left above the stitches, as contact of the stitches 30 of one die with the next die above may result in an electrical short. As shown in FIG. 2, it is therefore known to provide a dielectric spacer layer 34 to provide enough room for the stitches 30 to be bonded to the die bond pad on the lower die 24. Instead of a spacer layer 34, it is also known to bury the wire stitches between two adjacent semiconductor die within an adhesive layer between the respective die. Such configurations are shown for example in U.S. Pat. No. 6,388,313 to Lee et al., entitled, “Multi-Chip Module,” and U.S. Pat. No. 7,037,756 to Jiang et al., entitled, “Stacked Microelectronic Devices and Methods of Fabricating Same.”

There is an ever-present drive to increase storage capacity within memory modules. One method of increasing storage capacity is to increase the number of memory die used within the package. In portable memory packages, the number of die which may be used is limited by the thickness of the package. There is accordingly a keen interest in decreasing the thickness of the contents of a package while increasing memory density.

The package 20 shown in prior art FIGS. 1 and 2 requires that additional space be provided within the package to accommodate the height of the wire stitches. Further details relating to conventional processes for forming stitches 30 are explained with reference to the perspective views of prior art FIGS. 3-5. In FIGS. 3-5, the die 22 and 24 have been mounted to substrate 26. FIG. 3 shows stitches 30 formed by a forward ball bonding process. This process uses a wire bonding device referred to as a wire bonding capillary. A length of wire (typically gold or copper) is fed through a central cavity of the wire bonding capillary. The wire protrudes through a tip of the capillary, where a high-voltage electric charge is applied to the wire from a transducer associated with the capillary tip. The electric charge melts the wire at the tip and the wire forms into a ball (38 in FIG. 3) owing to the surface tension of the molten metal.

As the ball solidifies, the capillary is lowered to the surface of a die bond pad 40 formed on the semiconductor die 24. The surface of die 24 may be heated to facilitate a better bond. The stitch ball 38 is deposited on the die bond pad 40 under a load, while the transducer applies ultrasonic energy. The combined heat, pressure, and ultrasonic energy create a wire bond between the stitch ball 38 and the die bond pad 40.

The wire bonding capillary is then pulled up and away from the surface of semiconductor die 24, as wire is payed out through the capillary. The capillary then moves over to a contact pad 44 receiving the second end of the stitch on the substrate 26. The second wire bond, referred to as a wedge or tail bond, is then formed on contact pad 44 again using heat, pressure and ultrasonic energy, but instead of forming a ball, the wire is crushed under pressure to make the second wire bond. The wire bonding device then pays out a small length of wire and tears the wire from the surface of the second wire bond. The small tail of wire hanging from the end of the capillary is then used to form the stitch ball 38 for the next subsequent stitch. The above-described cycle can be repeated about 20 to 30 times per second until all stitches 30 are formed between the semiconductor die and the substrate. It is understood that there may be many more stitches 30 than are shown in FIGS. 3 and 4.

Due to the fact that the wire stitch 30 must be pulled upwards from ball 38 on each stitch 30, the stitches shown in FIG. 3 formed by the forward ball bonding process have a relatively large height. As indicated above, this height adds to the overall thickness of the package where space is at a premium. Prior art FIG. 4 is a perspective view of die 22, 24, substrate 26 and stitches 30 formed by a reverse ball bonding process. In a reverse ball bonding process, a stitch ball 50 is initially formed on the die bond pads 40 of semiconductor die 24. Namely, the capillary forms the ball and bonds it to the bond pad 40, but pulls away without paying out wire. This process is repeated to deposit a ball 50 on each bond pad 40 on die 24. Thereafter, to form a first wire stitch, a second ball 52 is wire bonded on a contact pad 44 of the substrate 26, and the capillary pulls up and away from the ball 52 while paying out wire. The capillary then wire bonds the stitch 30 to the corresponding ball 50 on the die bond pad 40 using a wedge bond. As the capillary attaches the stitch 30 to the ball 50 using a flat wedge bond, the stitch has a lower profile than in the forward ball bonding process of FIG. 3, where the wire was lifted up and away from the ball 38 on the die bond pads. This process is repeated to form the respective stitches between die 24 and substrate 26.

Referring to prior art FIG. 5, it is then known to repeat that process to wire bond die 22. Namely, stitch balls 60 are first affixed to bond pads 40 of die 22. Then stitch balls 62 are formed on top of the wedge bonds on die 24. Wire is payed out and bonded to balls 60 to form the stitches 66 on die 22. This process may be repeated again for any additional die on the die stack. As shown, corresponding (aligned) die bond pads 40 on the different die 22 and 24 are electrically shorted together. Signals are sent to and from a particular die by enabling only one of the die in the stack (via a chip enable signal connection not shown), so that a signal may be sent along a particular stitch connection path but only the enabled die will respond.

A conventional reverse wire bonding process as described above with respect to FIGS. 4 and 5 results in a lower profile than the forward wire bonding process of FIG. 3. However, all stitches on die in the die stack (except the uppermost die) will have a ball-wire-ball configuration. That is, as shown for die 24 in FIG. 5, the stitches on the bond pads 40 include a ball 62 bonded on an end of stitch 30, which is in turn formed on ball 50.

Having a ball-wire-ball configuration on the die bond pads of all intermediate die in a die stack has drawbacks. First, having to add an extra stitch ball in a reverse wire bonding process adds processing steps and time to the fabrication process, especially considering the large number of bonds that are required in any given semiconductor package. Additionally, the ball-wire-ball configuration has a relatively cumbersome structure with a high stitch failure rate. In one example of a four-memory die micro SD package, the yield loss has been found to be about 2000 PPM (parts per million).

### SUMMARY OF THE INVENTION

An embodiment of the present invention relates to a low profile semiconductor package including at least first and second stacked semiconductor die mounted to a substrate. The first semiconductor die may be electrically coupled to the substrate with a plurality of stitches in a forward ball bonding process. The second semiconductor die may in turn be electrically coupled to the first semiconductor die using a second set of stitches bonded between the die bond pads of the first and second semiconductor die. The second set of stitches may each include a lead end having a stitch ball that is bonded to the bond pads of the second semiconductor die. The tail end of each stitch in the second set of stitches may be wedge bonded directly to lead end of a stitch in the first set of stitches.

Affixing the tail end of a stitch directly to the wire bond on the die below provides an improvement over a conventional system including a ball-wire-ball configuration. For example, the present system requires fewer steps and less fabrication time. In particular, conventional reverse bonding techniques required stitch balls to be formed at both the front and tail ends of the stitch. By contrast, the present invention only requires a stitch ball at the front end of a stitch. The tail end of a stitch may be wedge bonded directly to the lead end wire bond of the die below. This results in a reduction of the stitch formation cycle time by 30% to 50% as compared to conventional reverse bonding techniques. Moreover, instead of a conventional ball-wire-ball configuration, the wire-on-wire configuration of the present invention is less bulky, providing the benefits of reduced electrical noise and greater stability which leads to lower stitch fracture rates.

### DESCRIPTION OF THE DRAWINGS

FIG. 1 is a prior art edge view of a conventional semiconductor device including a pair of semiconductor die stacked in an offset relation.

FIG. 2 is a prior art edge view of a conventional semiconductor device including a pair of semiconductor die stacked in an overlapping relation and separated by a spacer layer.

FIG. 3 is a prior art partial perspective view of a conventional semiconductor device including a semiconductor die mounted and stitched to a substrate in a forward ball bonding process.

FIG. 4 is a prior art partial perspective view of a conventional semiconductor device including a semiconductor die mounted and stitched to a substrate using a reverse ball bonding process.

FIG. 5 is a prior art partial perspective view of a conventional semiconductor device including a semiconductor die mounted and stitched to the semiconductor die shown in FIG. 4.

FIG. 6 is a flowchart showing the fabrication of a semiconductor device according to the present invention.

FIG. 7 is an edge view of a semiconductor device during fabrication including a die stitched to a substrate.

FIG. 8 is a perspective view of a semiconductor device during fabrication including a die stitched to a substrate.

FIG. 9 is an edge view of a semiconductor device during fabrication including a first die stitched to a substrate and a second die stitched to the first die.

FIG. 10 is a perspective view of a semiconductor device during fabrication including a first die stitched to a substrate and a second die stitched to the first die.

FIG. 10A is an enlarged view of the wire bond of the second die stitched to the first die.

FIG. 11 is a perspective view of a semiconductor device during fabrication including a first die stitched to a substrate, a second die stitched to the first die and a third die stitched to the second die.

FIG. 12 is a cross-sectional edge view of a finished semiconductor device according to an embodiment of the present invention.

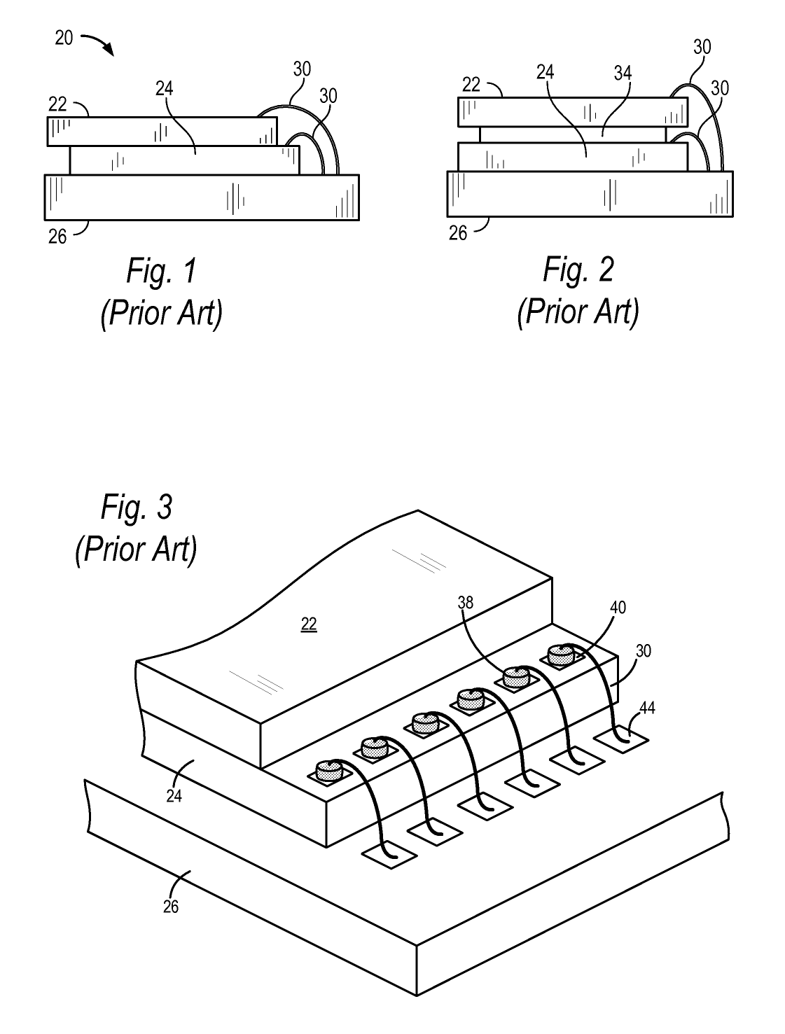

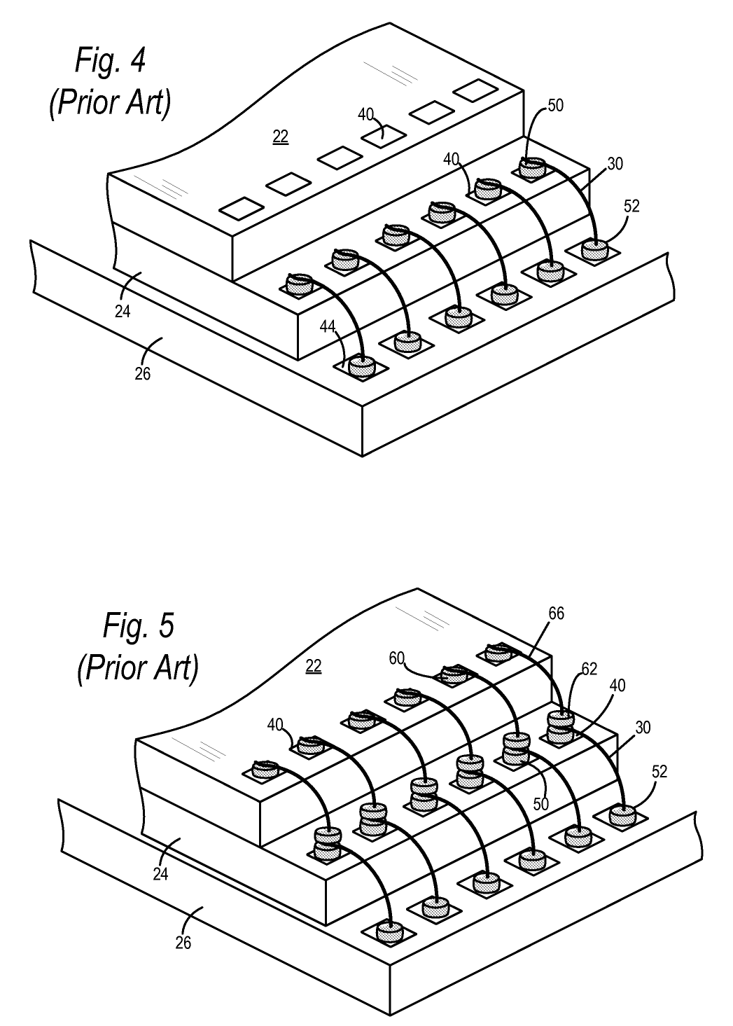

### DETAILED DESCRIPTION

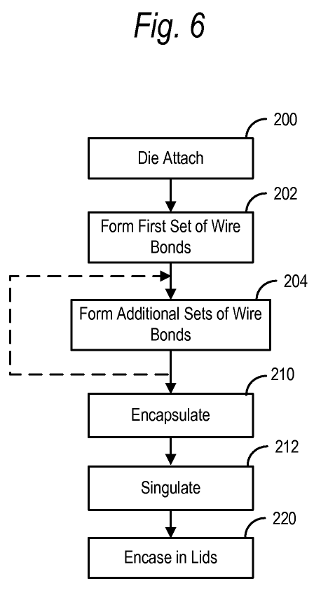

Embodiments will now be described with reference to FIGS. 6 through 12, which relate to a low profile semiconductor package. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom” and “upper” and “lower” are used herein for convenience and illustrative purposes only, and are not meant to limit the description of the invention inasmuch as the referenced item can be exchanged in position.

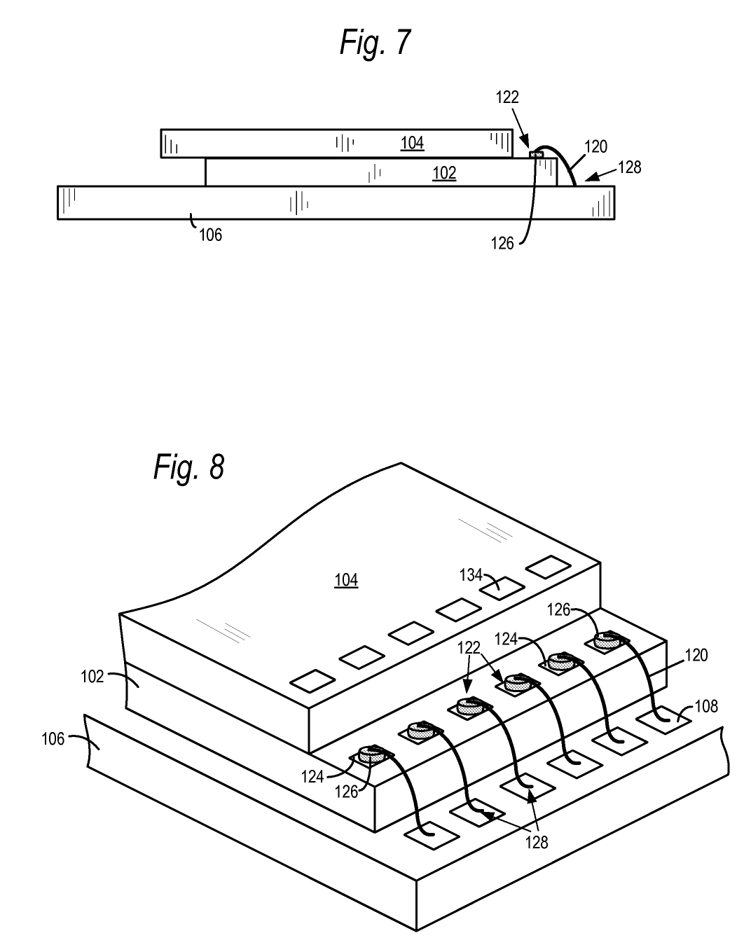

A process for forming a semiconductor package in accordance with the present invention will now be explained with reference to the flowchart of FIG. 6, and the views of FIGS. 7 through 12. Referring initially to the edge and perspective views of FIGS. 7 and 8, a first semiconductor die 102 may be mounted on a substrate 106 in a step 200. The die 102 may be mounted to substrate 106 via a die attach adhesive in a known adhesive or eutectic die bond process. Although not shown, substrate 106 may be part of a panel of substrates so that the semiconductor packages according to the present invention may be batch processed for economies of scale. Although fabrication of a single semiconductor package is described below, it is understood that the following description may apply to all packages formed on the substrate panel.

Although not critical to the present invention, substrate 106 may be a variety of different chip carrier mediums, including a PCB, a leadframe or a tape automated bonded (TAB) tape. Where substrate 106 is a PCB, the substrate may be formed of a core having top and/or bottom conductive layers formed thereon. The core may be various dielectric materials such as for example, polyimide laminates, epoxy resins including FR4 and FR5, bismaleimide triazine (BT), and the like.

The conductive layers may be formed of copper or copper alloys, plated copper or plated copper alloys, Alloy 42 (42FE/58NI), copper plated steel or other metals or materials known for use on substrates. The conductive layers may be etched into a conductance pattern as is known for communicating signals between the semiconductor die 102 and an external device (not shown). Substrate 106 may additionally include exposed metal portions forming contact pads 108 (shown for example in FIG. 8) on an upper surface of the substrate 106. Where the semiconductor package is a land grid array (LGA) package, contact fingers (not shown) may also be defined on a lower surface of the substrate 106. The contact pads 108 and/or contact fingers may be plated with one or more gold layers, for example in an electroplating process as is known in the art.

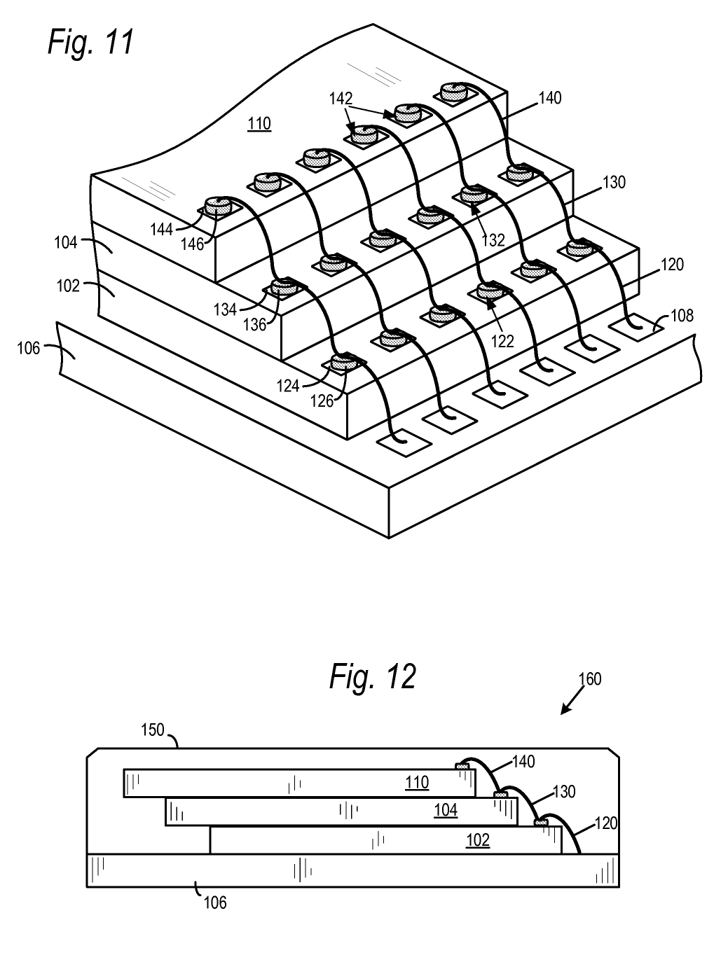

After the first semiconductor die 102 is affixed to substrate 106 in step 200, one or more additional die may be mounted on die 102 in an offset configuration. For example, FIGS. 7-10 show one additional die 104 mounted on die 102. FIGS. 11 and 12 show two additional die 104 and 110 mounted on die 102. It is understood that the die stack may include more than two additional die in further embodiments.

As shown in FIGS. 7 and 8, a first set of wire stitches 120 may be attached in step 202 between die bond pads 124 on die 102 and contact pads 108 on substrate 106 in a conventional forward ball bonding process. First, a wire bond 122 may be formed between stitches 120 and die bond pads 124 on die 102. This may be accomplished with a wire bonding capillary device of known construction (not shown), which forms and deposits a stitch ball 126 on a bond pad 124 of die 102. The ball 126 may be applied to the bond pad 124 under a load, while the transducer applies ultrasonic energy. The combined heat, pressure, and ultrasonic energy create wire bond 122 between the stitch ball 126 and the die bond pad 124. In embodiments, the stitch bonding process described above, as well as those described hereinafter, may be further facilitated by heating the surface the bond pad receiving the lead or tail end of a stitch.

A second wire bond 128, for example a wedge bond, is then formed between the wire 120 and substrate 106. In particular, after forming the first wire bond 122, the capillary pulls up and away from the ball 126 while paying out wire and bonds the wire to the corresponding contact pad 108 on substrate 106 to complete a stitch 120. The stitch 120 may be applied to the contact pad 108 under a load, while the transducer applies ultrasonic energy. The combined heat, pressure, and ultrasonic energy create a bond between the stitch 120 and the contact pad 108. The wire bonding capillary then pays out a small length of wire and tears the wire from the surface of the contact pad 108. The small tail of wire hanging from the end of the capillary is then used to form the stitch ball 126 for the next subsequent stitch. The above-described cycle can be repeated until all stitches 120 are formed between the die 102 and the substrate 106. It is understood that there may be many more stitches 120 than are shown in FIG. 8.

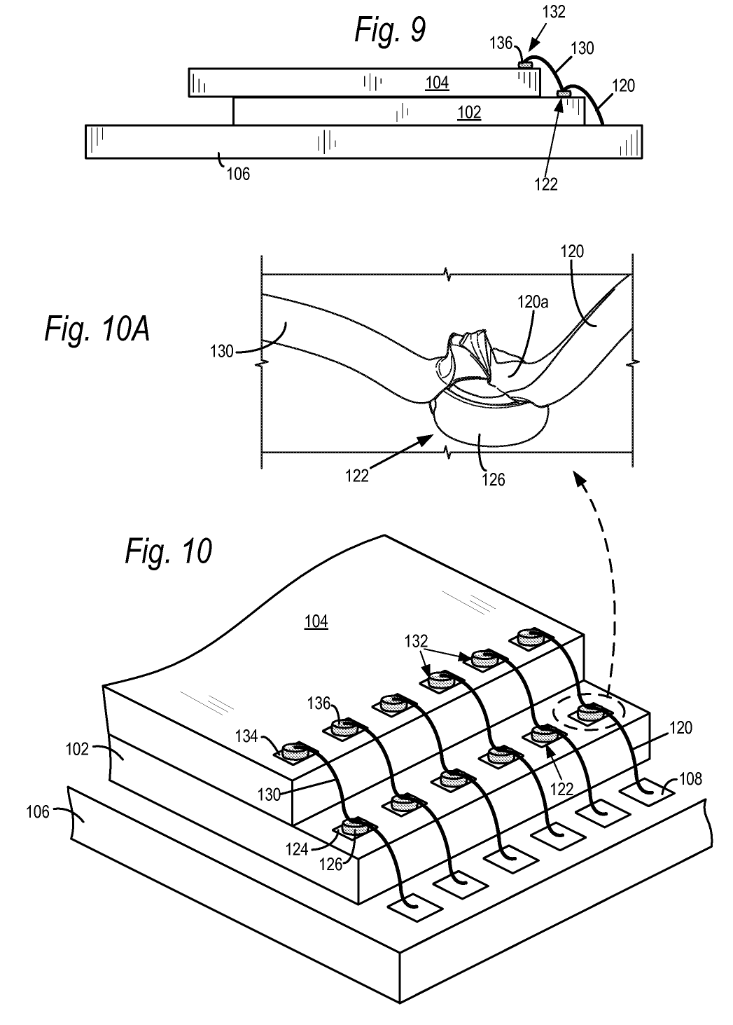

Referring now to FIGS. 9 through 10A, in accordance with the present invention, a second set of stitches 130 may next be formed having a first wire bond 132 on the die 104 and a second wire bond on top of the wire bond 122 on bond pad 124 of die 102. In step 204, the wire bonding capillary device may form and deposit a stitch ball 136 on a bond pad 134 of die 104. The ball 136 may be applied to the bond pad 134 under a load, while the transducer applies ultrasonic energy.

Next, the capillary pulls up and away from the ball 136 while paying out wire and completes the stitch 130 by attaching the tail end of the stitch 130 directly on top of the wire bond 122. The wire for stitch 130 may be bonded on top of wire bond 122 under a load, while the transducer applies ultrasonic energy. FIG. 10A is an enlarged view showing a tail end 130a of a stitch 130 connected to a wire bond 122. FIG. 10A shows a wire bond 122 including stitch ball 126 affixed to a die bond pad 124, and the stitch 120 extending therefrom. End 130a of stitch 130 is driven into and attached to wire bond 122 using the combined heat, pressure, and ultrasonic energy applied by the wire bonding capillary device.

In one embodiment, the capillary may apply a current of 60 mAps and a force of 35 grams over a period of 14 milliseconds in order to bond end 130a of stitch 130 with wire bond 122. This pressure and ultrasonic energy are sufficient to affix and electrically couple the end 130a of stitch 130 to the wire bond 122 on die bond pad 124. It is understood that the above-described current, force and/or time with which tail end 130a is affixed to wire bond 122 are by way of example only, and parameters may vary above and below the values given above in further embodiments. It is further understood that the process for affixing the tail end 130a of a stitch 130 to wire bond 122 may include the physical connection of the tail 130a to a portion of the stitch 120 extending from the stitch ball 126, the physical connection of the tail 130a to the stitch ball 126 itself, or both.

As seen in FIG. 10A, the capillary may partially flatten out the stitch 120 (for example at a section 120a) extending from wire bond 122 upon the affixation of end 130a of stitch 130. In addition to providing a flat bonding surface for connection of the tail end 130a, flattening out the stitch 120 extending from wire bond 122 may further serve to reduce the height of stitch 120.

After tail end 130a is affixed to wire bond 122, the wire bonding capillary then pays out a small length of wire and tears the wire from the surface of the wire bond 122. The small tail of wire hanging from the end of the capillary is then used to form the stitch ball 136 for the next subsequent stitch. The above-described cycle can be repeated until all stitches 130 are formed between the die 104 and the wire bonds 122 on die 102. It is understood that there may be many more stitches 130 than are shown in FIG. 10.

A system of stitching according to the present invention provides an improvement over a conventional system including a ball-wire-ball configuration as discussed in the Background of the Invention section. First, the present system requires fewer steps and less fabrication time. In particular, conventional reverse bonding techniques required stitch balls to be formed at both the front and tail ends of the stitch. By contrast, the present invention only requires a stitch ball at the front end of a stitch. The tail end of a stitch may be wedge bonded directly to the front end wire bond of the die below. This results in a reduction of the stitch formation cycle time for example by 30% to 50% as compared to conventional reverse bonding techniques. Moreover, instead of a ball-wire-ball configuration, a wire bond on an intermediate die (i.e., below the uppermost die in the stack) has a wire-on-wire configuration that is less bulky, providing the benefits of reduced electrical noise and greater stability. Greater stability leads to lower stitch fracture rates. For example, where a four-die Micro SD package of the prior art may have yield losses of 2000 PPM, the same package wire bonded according to the present invention may have yield losses of under 400 PPM.

Depending on how many semiconductor die are included in the stack, step 204 may be repeated (as indicated by the dashed arrow in FIG. 6) to form stitches on any additional semiconductor die in the die stack. For example, in FIGS. 7-10, there are only two semiconductor die, so after stitches 130 are formed, the wired semiconductor package may be encapsulated and singulated as explained below. However, in FIGS. 11-12, the die stack includes a third semiconductor die 110. Accordingly, step 204 is repeated so that stitches 140 are formed as described above. Namely, a front end of a stitch 140 is attached to a bond pad 144 and a tail end of a stitch 140 is affixed directly on top of a wire bond 132 on die 104. It is understood that step 204 may be repeated one or more additional times in the event there are one or more additional die mounted on top of die 110.

In the embodiments described above, all of the die in the die stack are first mounted on the substrate, and then they are wire bonded together. In an alternative embodiment, a die may be affixed to the stack and then wire bonded as described above before the next die in the stack is added.

In the above-described embodiments, the stitches may be uncoated gold, though it may alternatively be copper, aluminum or other metals. In a further embodiment of the present invention, the stitches may be pre-insulated with polymeric insulation that makes the surface of the wire electrically non-conductive. Two examples of a pre-insulated stitches which are suitable for use in the present invention are disclosed in U.S. Pat. No. 5,396,106, entitled, “Resin Coated Bonding Wire, Method Of Manufacturing The Same, And Semiconductor Device,” and U.S. Published Patent Application No. 2004/0124545, entitled, “High Density Integrated Circuits And The Method Of Packaging the Same,” both of which are incorporated by reference herein in their entirety.

As shown in FIG. 12, after forming the die stack and electrically coupling the die stack to each other and the substrate 106, the die stack may be encased within the molding compound 150 in step 210. Molding compound 150 may be a known epoxy such as for example available from Sumitomo Corp. and Nitto Denko Corp., both having headquarters in Japan. As indicated above, the semiconductor packages are formed a number at a time on a panel. Accordingly, after encapsulation, the respective packages may be singulated from the panel in step 212 to form a finished semiconductor package 160. In some embodiments, the finished package 160 may optionally be enclosed within a lid in step 220.

As shown in the figures, all corresponding (aligned) stitches in the different semiconductor die in the stack are electrically shorted together. For example, in FIG. 11, the three stitches 120, 130 and 140 that are labeled along the right-most edge of the die 102, 104 and 110 are shorted together. Signals are sent to and from a particular die 102, 104 or 110 by enabling only one of the die in the stack (via a chip enable signal connection not shown), so that a signal may be sent along a particular stitch connection path but only the enabled die will receive the signal and respond.

Semiconductor package 160 as shown in FIG. 12 may be used as a flash memory device. In such embodiments, the semiconductor die 102, 104 and/or 110 used within package 160 may be flash memory chips. In addition to the die 102, 104 and 110, the package 160 may also include a controller such as an ASIC, so that the package 160 may be used as a flash memory device. In embodiments, a finished package 160 may include four memory die and a controller die wire bonded as described above. In further embodiments, a finished package 160 may include eight memory die and a controller die wire bonded as described above. It is understood that the package 160 may include other numbers of memory die.

Package 160 may be used in a standard flash memory enclosure, including for example an SD card, compact flash, smart media, mini SD card, MMC and xD card, or a memory stick. Other standard flash memory packages are also possible. Package 160 may alternatively include semiconductor die configured to perform other functions in further embodiments of the present invention.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a substrate including a plurality of contact pads;
a first semiconductor die mounted to the substrate, the first semiconductor die including a plurality of bond pads;
a first set of stitches wire bonded between the die bond pads of the first semiconductor die and the contact pads of the substrate;
a second semiconductor die mounted on the first semiconductor die, the second semiconductor die including a plurality of bond pads;
a second set of stitches having lead ends bonded to the die bond pads of the second semiconductor die and tail ends wedge bonded on top of the first set of stitches wire bonded to the die bond pads of the first semiconductor die.

2. The semiconductor device of claim 1, further comprising molding compound encapsulating at least the first and second semiconductor die and first and second sets of stitches.

3. The semiconductor device of claim 1, wherein the first set of stitches include a lead end having a stitch ball affixed to the die bond pads of the first semiconductor die.

4. The semiconductor device of claim 3, wherein the tail ends of the second set of stitches are wedge bonded to portions of the first set of stitches extending from the stitch balls at the end of the first set of stitches.

5. The semiconductor device of claim 3, wherein the tail ends of the second set of stitches are wedge bonded to the stitch balls at the end of the first set of stitches.

6. The semiconductor device of claim 1, wherein the lead ends of the second set of stitches include stitch balls affixed to the die bond pads of the second semiconductor die.

7. The semiconductor device of claim 1, wherein the first and second stitches are formed of one of gold, aluminum and copper.

8. The semiconductor device of claim 1, wherein the first and second semiconductor die are flash memory die.

9. The semiconductor device of claim 8, further comprising a controller die electrically coupled to the substrate.

10. The semiconductor device of claim 1, wherein the semiconductor device is a flash memory device.

11. The semiconductor device of claim 10, wherein the flash memory device is one of an SD card, compact flash, smart media, mini SD card, MMC and xD card, or a memory stick.

12. A semiconductor device, comprising:
a substrate including a plurality of contact pads;
a first semiconductor die mounted to the substrate, the first semiconductor die including a plurality of bond pads;
a first set of stitches having lead ends formed into stitch balls, the stitch balls bonded to the die bond pads of the first semiconductor die and tail ends wedge bonded to the substrate.
a second semiconductor die mounted on the first semiconductor die, the second semiconductor die including a plurality of bond pads;
a second set of stitches having lead ends formed into stitch balls, the stitch balls bonded to the die bond pads of the second semiconductor die and tail ends wedge bonded on top of the first set of stitches wire bonded to the die bond pads of the first semiconductor die.

13. The semiconductor device of claim 12, further comprising molding compound encapsulating at least the first and second semiconductor die and first and second sets of stitches.

14. The semiconductor device of claim 12, further comprising:
a third semiconductor die including die bond pads; and
a third set of stitches having lead ends formed into stitch balls, the stitch balls bonded to the die bond pads of the third semiconductor die and tail ends wedge bonded on top of the second set of stitches wire bonded to the die bond pads of the second semiconductor die.

15. The semiconductor device of claim 12, wherein the tail ends of the second set of stitches are wedge bonded to portions of the first set of stitches extending from the stitch balls at the end of the first set of stitches.

16. The semiconductor device of claim 12, wherein the tail ends of the second set of stitches are wedge bonded to the stitch balls at the end of the first set of stitches.

17. A semiconductor device, comprising:
a substrate including a plurality of contact pads;
a plurality of semiconductor die, mounted to the substrate and stacked on top of each other in an offset configuration, each semiconductor die of the plurality of semiconductor die including a plurality of die bond pads;
a plurality of stitch sets, each stitch in each stitch set including a lead end formed into a stitch ball and bonded to a die bond pad of the plurality of die bonds of a semiconductor die, and a tail end wedge bonded to the lead end of a stitch on the die bond pad of the adjacent semiconductor die.

18. The semiconductor device of claim 17, wherein the tail end of the stitch is wedge bonded to a portion of the stitch extending from the stitch ball on a die bond pad of the adjacent semiconductor die.

19. The semiconductor device of claim 17, wherein the tail end of the stitch is wedge bonded to the stitch ball on a die bond pad of the adjacent semiconductor die.
